(19) United States
(12) Patent Application Publication
(10) Pub. No.: US 2015/0065608 A1
(43) Pub. Date: Mar. 5, 2015

(54) INSULATING RESIN COMPOSITION FOR PRINTED CIRCUIT BOARD AND PRODUCTS MANUFACTURED BY USING THE SAME

(71) Applicant: SAMSUNG ELECTRO-MECHANICS CO., LTD., Suwon-Si (KR)

(72) Inventors: Geum Hee Yun, Suwon-Si (KR); Jin Seok Moon, Suwon-Si (KR); Dae Hui Jo, Suwon-Si (KR); Seong Hyun Yoo, Suwon-Si (KR); Hyun Jun Lee, Suwon-Si (KR); Jin Young Kim, Suwon-Si (KR)

(73) Assignee: SAMSUNG ELECTRO-MECHANICS CO., LTD., Suwon-Si (KR)

(21) Appl. No.: 14/249,239

(22) Filed: Apr. 9, 2014

(30) Foreign Application Priority Data
Sep. 3, 2013 (KR) 10-2013-0105567

(51) Int. Cl. H05K 1/03; C08L 63/00

(52) U.S. Cl. CPC H05K 1/0366; C08L 63/00; C08L 2205/03; C08L 2203/20; H05K 2201/0275
USPC 523/435; 525/486

(57) ABSTRACT

Disclosed herein are an insulating resin composition for a printed circuit board and products manufactured by using the same, and more particularly, an insulating resin composition for a printed circuit board including an amino triazine novolac curing agent having an amino group and a hydroxyl group to have improved coefficient of thermal expansion and glass transition temperature properties, and improved acid resistant property that discoloration of the product is not generated, and an insulating film and a prepreg as products manufactured by using the same.

### CROSS REFERENCE TO RELATED APPLICATION

This application claims the benefit of Korean Patent Application No. 10-2013-0105567, filed on Sep. 3, 2013, entitled “Insulating Resin Composition for Printed Circuit Board and Products Manufactured by Using the Same”, which is hereby incorporated by reference in its entirety into this application.

### BACKGROUND OF THE INVENTION

1. Technical Field

The present invention relates to an insulating resin composition for a printed circuit board and products manufactured by using the same.

2. Description of the Related Art

In accordance with development of electronic devices, a printed circuit board has progressed to have a light weight, a thin thickness, and a small size. In order to satisfy the above-described demands, wirings of the printed circuit board have become more complicated and are densely formed. Electrical, thermal, and mechanical properties required for the board as described above are more important factors. The printed circuit board is configured of a copper mainly serving as a circuit wiring and a polymer serving as an interlayer insulation. As compared to the copper, various properties such as coefficient of thermal expansion, glass transition temperature, and thickness uniformity, are demanded in a polymer configuring an insulating layer, in particular, the insulating layer should be designed so as to have a thin thickness.

As the circuit board becomes thin, the board itself has decreased rigidity, causing defects due to a bending phenomenon at the time of mounting components thereon at a high temperature. Therefore, thermal expansion property and heat-resistant property of a heat curable polymer resin function as an important factor, that is, at the time of heat curing, network between polymer chains configuring a polymer structure and a board composition and curing density are closely affected.

In the prior art, a composition for forming a board, including a liquid crystal oligomer and an epoxy-based resin is disclosed, wherein the liquid crystal oligomer is an oligomer having liquid crystallinity and including hydroxyl groups introduced at both ends, and the epoxy-based resin has four functional groups introduced therein, that is, N,N,N′,N′-tetraglycidyl-4,4′-methylenebisbenzenamine. The liquid crystal oligomer and the epoxy-based resin are mixed in N,N′-dimethylacetamide (DMAc) together with dicyandiamide in a predetermined mixed ratio to prepare the composition. In order to cure the liquid crystal oligomer having the hydroxyl group introduced therein in the composition, the epoxy-based resin, N,N,N′,N′-tetraglycidyl-4,4′-methylenebisbenzenamine is added for heat curing, which is not appropriate in view of a decrease in coefficient of thermal expansion (CTE) and an increase in glass transition temperature (Tg) which are important in materials of the printed board, due to flexibility in the molecular chains between the hydroxyl group and epoxy-based resin produced by reaction with a multi-functional epoxy resin. In addition, at the time of performing an etching process using acid products in manufacturing the circuit board, an acid component is adsorbed on an amine group present in an N,N,N′,N′-tetraglycidyl-4,4′-methylenebisbenzenamine epoxy resin. The above-described phenomenon may cause discoloration of a prepreg, resulting in a product's defect.

Meanwhile, Patent Document 1 discloses a heat curable composition including a liquid crystal oligomer, a bismaleimide-based compound, an epoxy compound, and a fluorinated polymer resin powder, but has a problem in that an interaction network between compositions is not sufficiently formed, such that a glass transition temperature which is suitable for the printed circuit board is not achieved.

### PRIOR ART DOCUMENT

(Patent Document 1) Korean Patent Laid-Open Publication No. KR 2011-0108782

### SUMMARY OF THE INVENTION

In the present invention, it is confirmed that an insulating resin composition for a printed circuit board, the insulating resin composition including a liquid crystal oligomer (LCO); a naphthalene-based epoxy resin; a bismaleimide (BMI) resin, and an amino triazine novolac (ATN) curing agent, and products manufactured by using the same have improved coefficient of thermal expansion and glass transition temperature properties, and have improved acid resistant property that discoloration of the product is not generated, thereby completing the present invention.

Therefore, the present invention has been made in an effort to provide the insulating resin composition for the printed circuit board having the improved coefficient of thermal expansion, glass transition temperature, and acid resistant properties.

In addition, the present invention has been made in an effort to provide an insulating film prepared by applying and curing a varnish containing the insulating resin composition on a substrate.

Further, the present invention has been made in an effort to provide a prepreg prepared by impregnating an inorganic fiber or an organic fiber into a varnish containing the insulating resin composition.

According to a preferred embodiment of the present invention, there is provided an insulating resin composition for a printed circuit board including: a liquid crystal oligomer; a naphthalene-based epoxy resin; a bismaleimide resin; and an amino triazine novolac curing agent.

The insulating resin composition may include the liquid crystal oligomer in an amount of 10 to 30 wt %, the naphthalene-based epoxy resin in an amount of 20 to 40 wt %, the bismaleimide resin in an amount of 10 to 30 wt %, and the amino triazine novolac curing agent in an amount of 3 to 20 wt %.

The liquid crystal oligomer may be represented by the following Chemical Formula 1, Chemical Formula 2, Chemical Formula 3, or Chemical Formula 4:

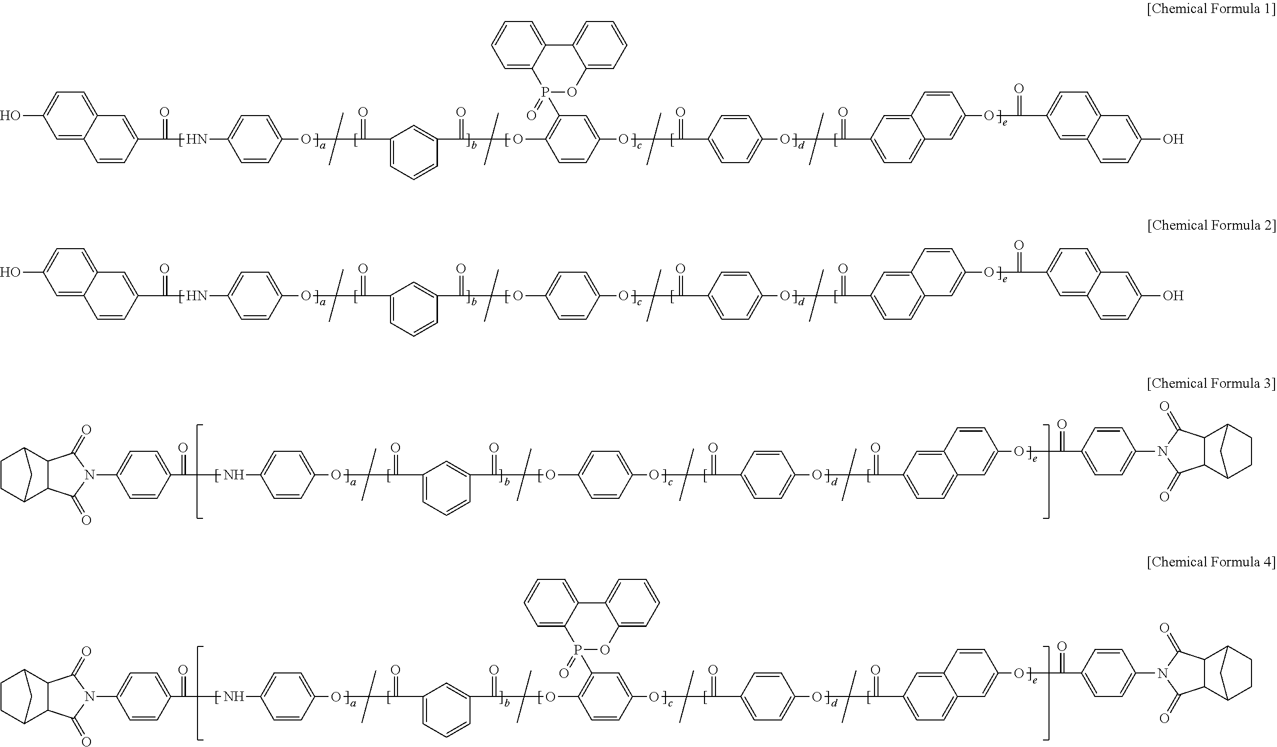

in Chemical Formulas 2 to 4, a is an integer of 13 to 26, b is an integer of 13 to 26, c is an integer of 9 to 21, d is an integer of 10 to 30, and e is an integer of 10 to 30.

The naphthalene-based epoxy resin may be represented by the following Chemical Formula 5, Chemical Formula 6, Chemical Formula 7, or Chemical Formula 8:

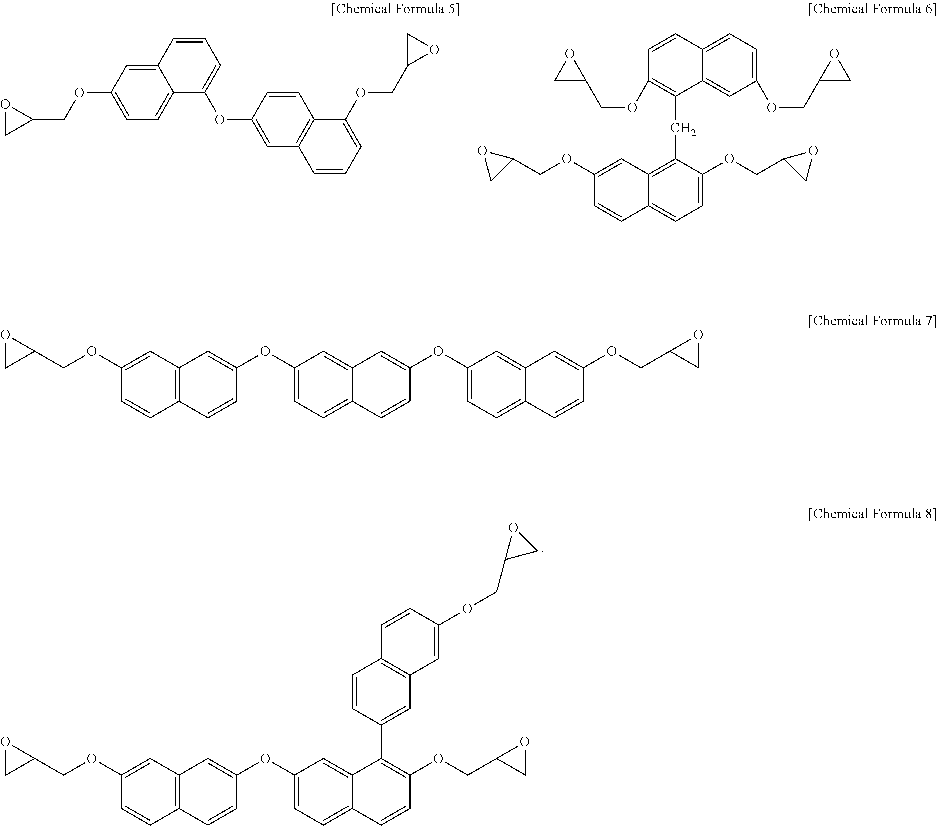 [SMILES: c1cc(OCC2CO2)c2ccc(Oc3cccc4cc(OCC5CO5)ccc34)cc2c1 ; c1cc2ccc(OCC3CO3)c(Cc3c(OCC4CO4)ccc4ccc(OCC5CO5)cc34)c2cc1OCC1CO1 ; c1cc2ccc(Oc3ccc4ccc(Oc5ccc6ccc(OCC7CO7)cc6c5)cc4c3)cc2cc1OCC1CO1 ; c1cc2ccc(Oc3ccc4ccc(OCC5CO5)c(-c5ccc6ccc(OCC7CO7)cc6c5)c4c3)cc2cc1OCC1CO1]

The bismaleimide resin may be represented by the following Chemical Formula 9 or Chemical Formula 10:

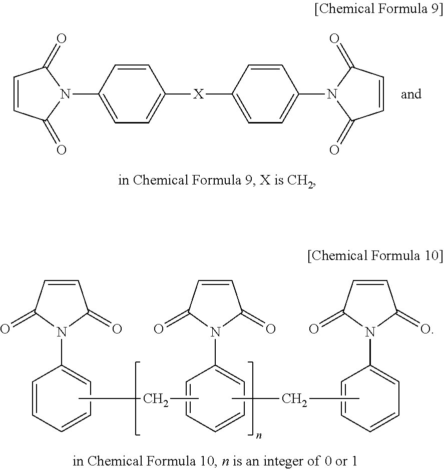

The amino triazine novolac curing agent may include an amino group and a hydroxyl group, and may be represented by the following Chemical Formula 11, Chemical Formula 12, or Chemical Formula 13:

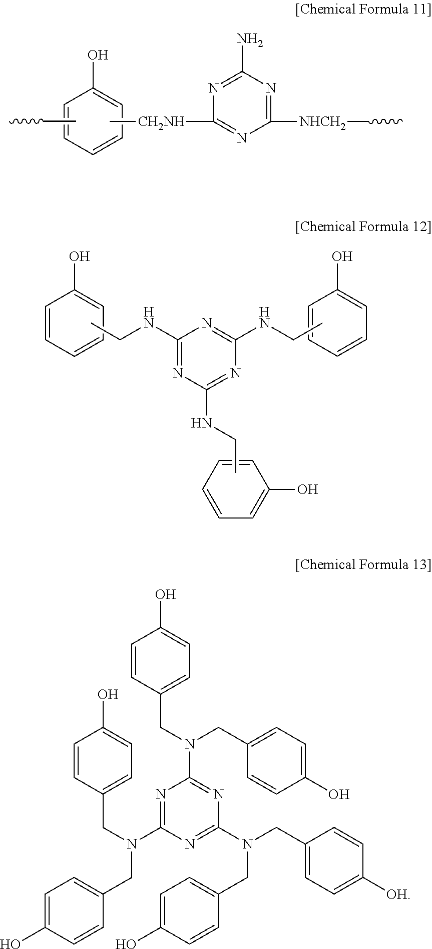

The insulating resin composition may further include an inorganic filler, a coupling agent, a dispersant, an initiator, a surface treating agent, a defoaming agent, and a curing accelerator.

The inorganic filler may be included in an amount of 100 to 400 parts by weight based on 100 parts by weight of the insulating resin composition, and may be at least one selected from silica (SiO₂), alumina (Al₂O₃), barium sulfate (BaSO₄), talc, clay, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃).

The initiator may be at least one selected from azobisisobutyronitrile (AIBN), dicumyl peroxide (DCP) and di-tertiarybutyl peroxide (DTBP).

The curing accelerator may be at least one selected from a metal-based curing accelerator, an imidazole-based curing accelerator, and an amine-based curing accelerator.

According to another preferred embodiment of the present invention, there is provided an insulating film prepared by applying and curing a varnish containing the insulating resin composition as described above on a substrate.

According to another preferred embodiment of the present invention, there is provided a prepreg prepared by impregnating an inorganic fiber or an organic fiber into a varnish containing the insulating resin composition as described above.

The inorganic fiber or the organic fiber may be at least one selected from a glass fiber, a carbon fiber, a polyparaphenylenebenzobisoxazol fiber, a thermotropic liquid crystal polymer fiber, a lithotropic liquid crystal polymer fiber, an aramid fiber, a polypyridobisimidazole fiber, a polybenzothiazole fiber, and a polyarylate fiber.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a general printed circuit board to which an insulating resin composition according to a preferred embodiment of the present invention may be applied.

### DESCRIPTION OF THE PREFERRED EMBODIMENTS

Before the present invention is described in more detail, it must be noted that the terms and words used in the present specification and claims should not be interpreted as being limited to typical meanings or dictionary definitions, but should be interpreted as having meanings and concepts relevant to the technical scope of the present invention based on the rule according to which an inventor can appropriately define a concept implied by a term to best describe the method he or she knows for carrying out the invention. Further, the embodiments of the present invention are merely illustrative, and are not to be construed to limit the scope of the present invention, and thus there may be a variety of equivalents and modifications able to substitute for them at the point of time of the present application.

In the following description, it is to be noted that embodiments of the present invention are described in detail so that the present invention may be easily performed by those skilled in the art, and also that, when known techniques related to the present invention may make the gist of the present invention unclear, a detailed description thereof will be omitted.

An insulating resin composition for a printed circuit board according to a preferred embodiment of the present invention and products manufactured by using the same may include a liquid crystal oligomer; a naphthalene-based epoxy resin; a bismaleimide resin; and an amino triazine novolac curing agent, in order to improve coefficient of thermal expansion and glass transition temperature properties and achieve an improved acid resistant property that discoloration is not generated by an etching process using an acid solution in the products manufactured by using the same.

Liquid Crystal Oligomer

The insulating resin composition according to the preferred embodiment of the present invention may be represented by the following Chemical Formula 1, Chemical Formula 2, Chemical Formula 3, or Chemical Formula 4, and may include a liquid crystal oligomer containing a hydroxyl group (—OH), an amino group (—NH₂), and a carboxyl group (—COOH):

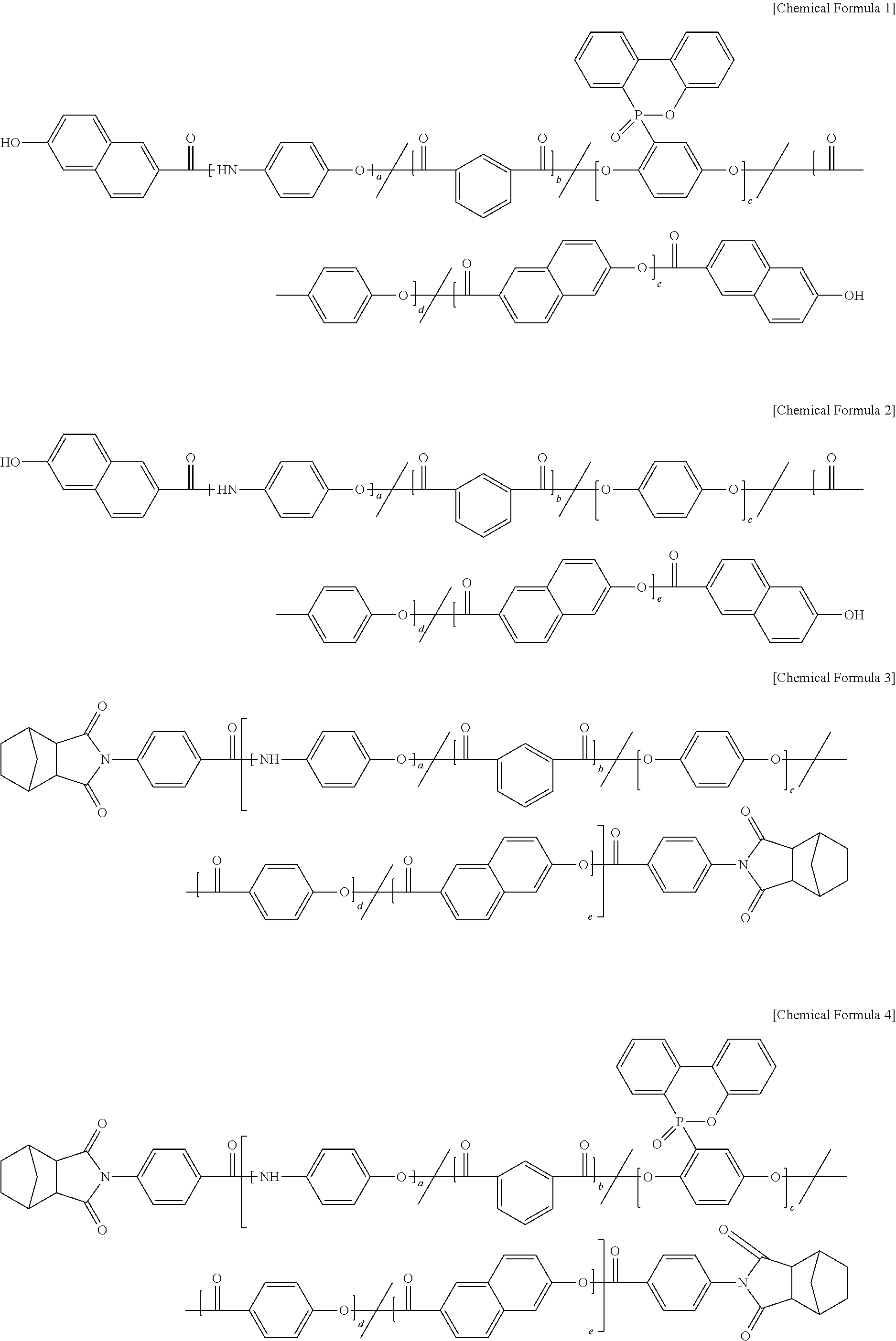

in Chemical Formulas 2 to 4, a is an integer of 13 to 26; b is an integer of 13 to 26; c is an integer of 9 to 21; d is an integer of 10 to 30; and e is an integer of 10 to 30.

In addition, as the liquid crystal oligomer, a liquid crystal oligomer represented by Chemical Formula 1 or Chemical Formula 2 above and including the hydroxyl groups introduced at both ends is the most appropriate in order to improve a curing reaction with the epoxy resin in the insulating resin composition.

The liquid crystal oligomer according to the preferred embodiment of the present invention is not specifically limited in view of a used amount, but is appropriate for being used in an amount of 10 to 30 wt %. In the case in which the used amount is less than 10 wt %, a decrease in coefficient of thermal expansion and an increase in glass transition temperature are not significant, and in the case in which the used amount is more than 30 wt %, the mechanical properties are deteriorated.

Naphthalene-Based Epoxy Resin

The insulating resin composition according to the preferred embodiment of the present invention may include a naphthalene-based epoxy resin. The naphthalene-based epoxy resin according to the preferred embodiment of the present invention may be represented by the following Chemical Formula 5, Chemical Formula 6, Chemical Formula 7, or Chemical Formula 8, and the epoxy resin represented by the following Chemical Formula 6 and having 4-functional groups, that is, bis(2,7-bis(2,3-epoxypropoxy))dinaphthalene methane is appropriate for increasing curing density between other compositions:

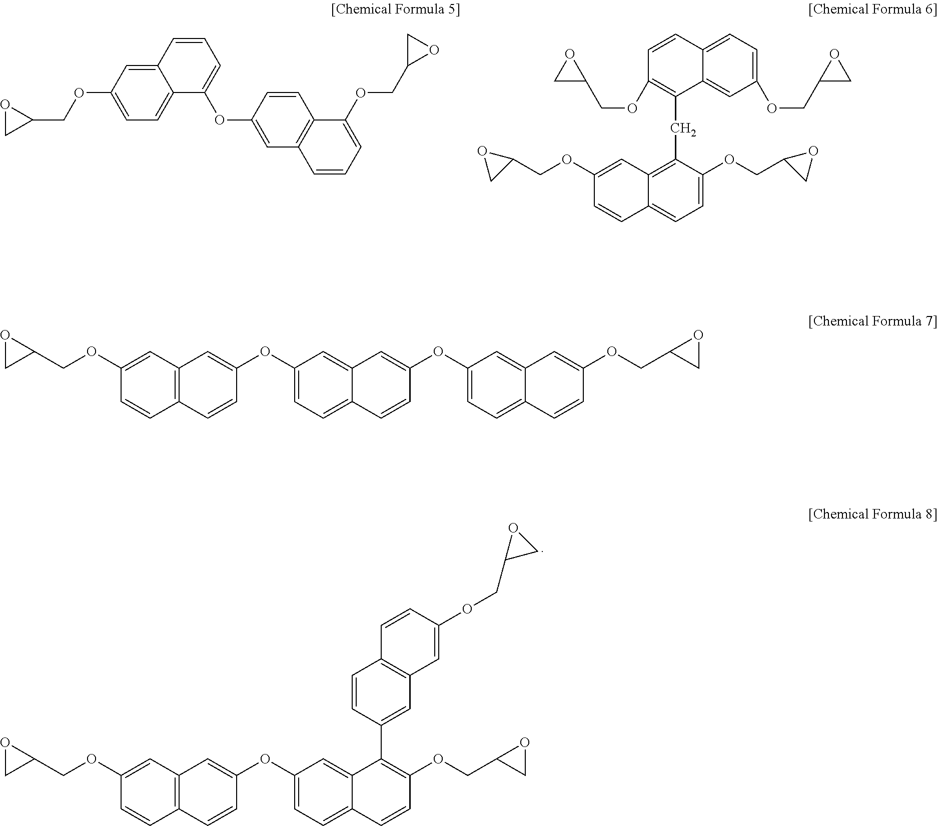 [SMILES: c1cc(OCC2CO2)c2ccc(Oc3cccc4cc(OCC5CO5)ccc34)cc2c1 ; c1cc2ccc(OCC3CO3)c(Cc3c(OCC4CO4)ccc4ccc(OCC5CO5)cc34)c2cc1OCC1CO1 ; c1cc2ccc(Oc3ccc4ccc(Oc5ccc6ccc(OCC7CO7)cc6c5)cc4c3)cc2cc1OCC1CO1 ; c1cc2ccc(Oc3ccc4ccc(OCC5CO5)c(-c5ccc6ccc(OCC7CO7)cc6c5)c4c3)cc2cc1OCC1CO1]

The naphthalene-based epoxy resin represented by Chemical Formulas 5 to 8 above may improve polymer crystallinity and have low thermal expansion rate and high heat-resistant property, due to a hard naphthalene mesogen structure in the insulating resin composition. An epoxide group at an end of the naphthalene-based epoxy resin may be reacted with the hydroxyl group of the liquid crystal oligomer, such that high curing density may be achieved. In addition, since the naphthalene-based epoxy resin represented by Chemical Formulas 5 to 8 above includes a naphthalene structure to be rigid, the naphthalene-based epoxy resin may have thermal stability. In addition, the naphthalene-based epoxy resin may configure an interconnected network with the liquid crystal oligomer and the bismaleimide resin in the resin composition, and may achieve the high heat-resistant property.

The naphthalene-based epoxy resin according to the preferred embodiment of the present invention is not specifically limited in view of a used amount, but is appropriate for being used in an amount of 20 to 40 wt %. In the case in which the used amount is less than 20 wt %, peel strength with a metal layer and chemical-resistant property may be deteriorated, and in the case in which the used amount is more than 40 wt %, added amounts of other components are relatively decreased, such that dielectric loss tangent, dielectric constant, and coefficient of thermal expansion are hardly improved, and mechanical properties may be deteriorated.

Bismaleimide Resin

The insulating resin composition according to the preferred embodiment of the present invention may include the bismaleimide resin represented by the following Chemical Formula 9 or Chemical Formula 10 in order to improve the heat-resistant property in the resin composition. In addition, as the bismaleimide resin, an oligomer of phenyl methane maleimide represented by the following Chemical Formula 10 is appropriate:

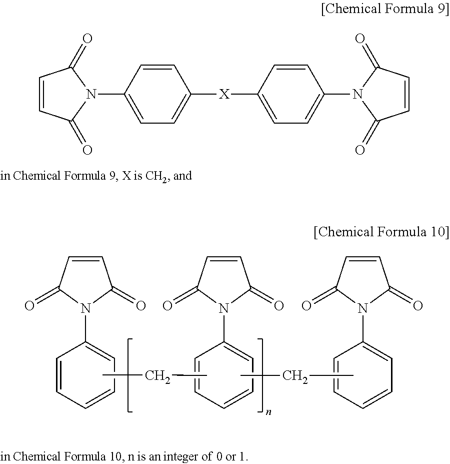

The bismaleimide resin represented by Chemical Formula 9 or Chemical Formula 10 above may have strong heat-resistant property in the resin composition, and at the time of heat curing, a double bonding structure in the maleimide resin may be coupled with the hydroxyl group of the liquid crystal oligomer by a Michael reaction to configure an interconnected network.

The bismaleimide resin according to the preferred embodiment of the present invention is not specifically limited in view of a used amount, but is appropriate for being used in an amount of 10 to 30 wt %. In the case in which the used amount is less than 10 wt %, the glass transition temperature is hardly improved, and in the case in which the used amount is more than 30 wt %, brittle is increased, such that it may be difficult to be manufactured as a product.

Amino Triazine Novolac Curing Agent

The insulating resin composition according to the preferred embodiment of the present invention may include an amino triazine novolac curing agent represented by the following Chemical Formula 11, Chemical Formula 12, or Chemical Formula 13. In addition, as the amino triazine novolac curing agent, a curing agent represented by the following Chemical Formula 11 is appropriate in order to maximize curing density and curing reactivity with other compositions:

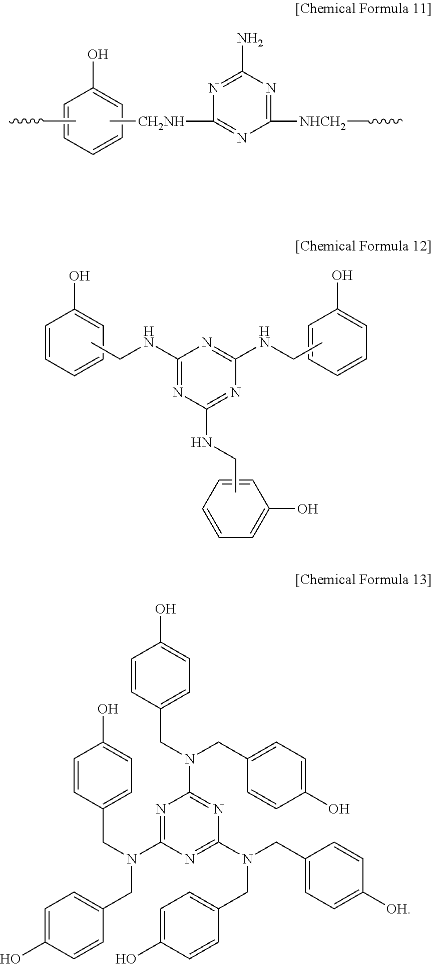

The amino triazine novolac curing agent represented by the following Chemical Formula 11 to Chemical Formula 13 may have all advantages of phenol novolac and dicyandiamide (DICY) curing agent, and may include an amino group and a hydroxyl group in the structure thereof to inhibit a homo-polymerization with the bismaleimide resin and to be included in a cross linkage. In addition, at the time of heat curing, the hydroxyl group of the amino triazine novolac curing agent may be reacted with the epoxide group of the naphthalene-based epoxy resin, and the amino group thereof may be coupled with the double bond structure of the bismaleimide resin by a Michael reaction to achieve a high order network among the liquid crystal oligomer, the naphthalene-based epoxy resin, and the bismaleimide resin, and to implement high heat-resistant property. In particular, in the case of applying the amino triazine novolac curing agent to the resin composition, the naphthalene-based epoxy resin and the bismaleimide resin may be simultaneously cured to achieve more stable curing reaction.

The amino triazine novolac curing agent according to the preferred embodiment of the present invention is not specifically limited in view of a used amount, but is appropriate for being used in an amount of 3 to 20 wt %. In the case in which the used amount is less than 3 wt %, a substance which is not cured may be left, and in the case in which the used amount is more than 20 wt %, thermal stability in the composition may be deteriorated.

The insulating resin composition according to another preferred embodiment of the present invention may further include an inorganic filler, a coupling agent, a dispersant, an initiator, a surface treating agent, a defoaming agent, and a curing accelerator.

The inorganic filler may be included in the insulating resin composition in order to decrease the coefficient of thermal expansion, wherein a ratio in which the inorganic filler is contained in the resin composition may be varied depending on properties required in consideration of the use of the resin composition, and the like, and for example, the inorganic filler may be included in an amount of 100 to 400 parts by weight based on 100 parts by weight of the insulating resin composition. In the case in which the contained amount of the inorganic filler is less than 100 parts by weight, the dielectric loss tangent tends to be decreased and the coefficient of thermal expansion tends to be increased, and in the case in which the contained amount of the inorganic filler is more than 400 parts by weight, adhesion strength tends to be deteriorated.

As the inorganic filler, silica (SiO₂), alumina (Al₂O₃), barium sulfate (BaSO₄), talc, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃) may be used alone or in combination of two or more kinds thereof. In particular, it is appropriate to use a silica (SiO₂) having lower dielectric loss tangent.

In addition, the dispersant for helping dispersion with the coupling agent may be further included in the composition in order to increase interface adhesion of the inorganic filler and thus to improve property as a composite material. As the coupling agent, glycidoxypropyl trimethoxy silane (GPTMS) or amino phenyl silane (APS) may be used, and the coupling agent may be included in an amount of 2 parts by weight based on 100 parts by weight of the inorganic filler. As the dispersant, BYK-2009, BYK-110, or BYK-103 (BYK-Chemie) may be used.

In the insulating resin composition according to another preferred embodiment of the present invention, the initiator of the bismaleimide resin may be at least one selected from azobisisobutyronitrile (AIBN), dicumyl peroxide (DCP) and di-tertiarybutyl peroxide (DTBP) and may be selectively contained to generate an effective reaction.

In addition, the insulating resin composition according to another preferred embodiment of the present invention may be effectively cured by selectively containing the curing accelerator. In addition, examples of the curing accelerator used in the present invention may include a metal-based curing accelerator, an imidazole-based curing accelerator, and an amine-based curing accelerator, and one kind or a combination of two or more kinds thereof may be used.

Examples of the metal-based curing accelerator may include an organic metal complex or an organic metal salt of a metal such as cobalt, copper, zinc, iron, nickel, manganese, tin, or the like, but the present invention is not limited thereto. Specific examples of the organic metal complex may include organic cobalt complex such as cobalt (II) acetylacetonate, cobalt (III) acetylacetonate, or the like, organic copper complex such as copper (II) acetylacetonate, organic zinc complex such as zinc (II) acetylacetonate, organic iron complex such as iron (III) acetylacetonate, organic nickel complex such as nickel (II) acetylacetonate, organic manganese complex such as manganese (II) acetylacetonate, and the like. Examples of the organic metal salts may include zinc octyl acid, tin octyl acid, zinc naphthenic acid, cobalt naphthenic acid, tin stearic acid, zinc stearic acid, and the like. As the metal-based curing accelerator, cobalt (II) acetylacetonate, cobalt (III) acetylacetonate, zinc (II) acetylacetonate, zinc naphthenic acid, iron (III) acetylacetonate are preferred, and in particular, cobalt (II) acetylacetonate and zinc naphthenic acid are more preferred. One kind or a combination of two or more kinds of the metal-based curing accelerator may be used.

Examples of the imidazone-based curing accelerator may include imidazole compounds such as 2-methylimidazole, 2-undecylimidazole, 2-heptadecylimidazole, 1,2-dimethylimidazole, 2-ethyl-4-methylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazoliumtrimellitate, 1-cyanoethyl-2-phenylimidazoliumtrimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazineisocyanic acid adduct, 2-phenyl-imidazoleisocyanic acid adduct, 2-phenyl-4,5-dihydroxymethylimidazole, 2-phenyl-4-methyl-5-hydroxymethylimidazole, 2,3-dihydroxy-1H-pyroro[1,2-a]benzimidazole, 1-dodecyl-2-methyl-3-benzyl-imidazoliumchloride, 2-methylimidazoline, and 2-phenyl-imidazoline, and an adduct of the imidazole compounds and the epoxy resin, but the present invention is not specifically limited thereto. One kind or a combination of two or more kinds of the imidazole-based curing accelerator may be used.

Examples of the amine-based curing accelerator may include trialkylamine such as triethylamine and tributylamine, and an amine compound such as 4-dimethylaminopyridine, benzyldimethylamine, 2,4,6-tris(dimethylamino-methyl)phenol, 1,8-diazabicyclo(5,4,0)-undecene, but the present invention is not specifically limited thereto. One kind or a combination of two or more kinds of the amine-based curing accelerator may be used.

In addition, the insulating resin composition according to the preferred embodiment of the present invention may further include BYKETOL-PC (BYK-Chemie) as a surface treating agent which is a kind of additives for preventing a surface dryness and BYK-057 (BYK-Chemie) as a defoaming agent for removing foam in the composition.

The insulating resin composition according to the preferred embodiment of the present invention may be fabricated as a dry film in a semi solid state by using any general method known in the art. For example, the film is fabricated by using a roll coater, a curtain coater, or a comma coater and dried, and then applied on a substrate to be used as the insulating film or the prepreg at the time of manufacturing a multilayer printed board by a build-up scheme. The insulating film or the prepreg may have improved coefficient of thermal expansion and glass transition temperature properties, and products manufactured by using the insulating film or the prepreg may have improved acid resistant property that discoloration is not generated by an etching process using an acid solution.

As described above, the insulating resin composition according to the preferred embodiment of the present invention is impregnated into a substrate such as the inorganic fiber or the organic fiber and cured to prepare the prepreg, and a copper clad is laminated thereon to obtain a copper clad laminate (CCL). In addition, copper clads may be laminated on both surfaces of the prepreg to obtain a copper clad laminate (CCL). Further, the insulating film prepared by the insulating resin composition according to the preferred embodiment of the present invention is laminated on the CCL used as an inner layer at the time of manufacturing the multilayer printed circuit board to be used in manufacturing the multilayer printed circuit board. For example, after the insulating film prepared by the insulating resin composition is laminated on an inner circuit board having processed patterns and cured at a temperature of 80 to 110° C. for 20 to 30 minutes, a desmear process is performed, and a circuit layer is formed through an electroplating process, thereby manufacturing the multilayer printed circuit board.

The inorganic fiber or organic fiber may be at least one selected from a glass fiber, a carbon fiber, a polyparaphenylenebenzobisoxazol fiber, a thermotropic liquid crystal polymer fiber, a lithotropic liquid crystal polymer fiber, an aramid fiber, a polypyridobisimidazole fiber, a polybenzothiazole fiber, and a polyalylate fiber.

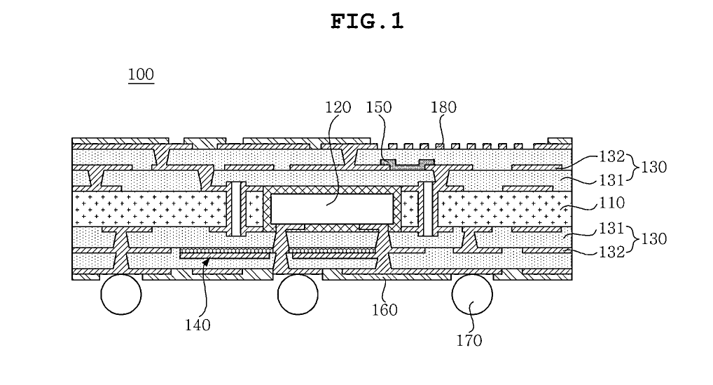

FIG. 1 is a cross-sectional view of a general printed circuit board in which an insulating resin composition according to a preferred embodiment of the present invention is applicable, and referring to FIG. 1, a printed circuit board 100 may be an embedded board with a built-in electronic component. More specifically, the printed circuit board 100 may include an insulator 110 having cavities, electronic components 120 disposed in the cavities, and a build-up layer 130 disposed on at least one of the upper and lower surfaces of the insulator 110 including the electronic component 120. The buildup layer 130 may include a circuit layer 132 disposed on at least one surface of the upper and lower surfaces of the insulator 110 and forming an interlayer connection. Here, an example of the electronic component 120 may include an active device such as a semiconductor device. In addition, in the printed circuit board 100, only one electronic component 120 is not embedded but at least one additional electronic components such as a capacitor 140 and a resistor device 150 may be embedded. Therefore, the preferred embodiment of the present invention is not limited in view of types or the number of electronic components. Further, in order to protect the circuit board, a solder resist 160 layer may be provided in the outermost portion. The printed circuit board may be provided with external connection units 170 according to electronic products to be mounted thereon, and sometimes provided with a pad 180 layer. Herein, the insulator 110 and the insulating layer 131 may serve to provide inter-circuit layer insulation and inter-electronic component insulation and also serve as a structural member for holding rigidity of the package. In this case, when a wiring density of the printed circuit board 100 is increased, the insulator 110 and the insulating layer 131 are required to have low dielectric constant in order to reduce both inter-circuit layer noise and simultaneously reduce parasitic capacitance, and are required to have low dielectric loss property in order to increase the insulating property. As described above, at least any one of the insulator 110 and the insulating layer 131 needs to decrease dielectric constant and dielectric loss and have rigidity.

Hereinafter, the present invention will be described in more detail with reference to the following examples and comparative examples; however, it is not limited thereto.

### Example 1

An oligomer of phenyl methane maleimide 15.68 g and a liquid crystal oligomer 15.68 g were mixed into a N,N′-dimethylacetamide (DMAc) solvent 43 g, followed by stirring for about 1 hour. Bis(2,7-bis(2,3-epoxypropoxy))dinaphthalene methane 21.84 g which is a naphthalene-based epoxy resin was added thereto, followed by stirring for about 2 hours. Then, an amino triazine novolac curing agent 2.8 g and azobisisobutyronitrile (AIBN) 0.1 g were added thereto, followed by stirring for about 1 hour, thereby preparing a completely dissolved resin composition. The resin composition in an adequate amount was poured onto a shiny surface of a copper clad, and a film having a thickness of about 150 um was obtained by a film caster for a lab. The film was primarily dried in an oven at about 80° C. for 30 minutes to remove a volatile solvent. Then, the film was secondarily dried at about 120° C. for 60 minutes to obtain a film at a B-stage. The film was completely cured by maintaining a temperature of about 230° C., and pressure of 30 kgf/cm³ for about 90 minutes using a vacuum press. After the curing was completed, the film was cut into a size of 4.3 mm/30 mm to prepare a measuring sample.

### Example 2

An oligomer of phenyl methane maleimide 11.2 g and a liquid crystal oligomer 8.4 g were mixed into a N,N′-dimethylacetamide (DMAc) solvent 43 g, followed by stirring for about 1 hour. Bis(2,7-bis(2,3-epoxypropoxy))dinaphthalene methane 28.04 g which is a naphthalene-based epoxy resin was added thereto, followed by stirring for about 2 hours. Then, an amino triazine novolac curing agent 8.4 g and azobisisobutyronitrile (AIBN) 0.15 g were added thereto, followed by stirring for about 1 hour, thereby preparing a completely dissolved resin composition. Afterward, the same process as Example 1 was performed to prepare a measuring sample of Example 2.

### Example 3

An oligomer of phenyl methane maleimide 27.56 g, a liquid crystal oligomer 25.01 g, and a silica (SiO₂) slurry 287.58 g were mixed into a N,N′-dimethylacetamide (DMAc) solvent 73.6 g, followed by stirring for about 1 hour. Bis(2,7-bis(2,3-epoxypropoxy))dinaphthalene methane 30.04 g which is a naphthalene-based epoxy resin was added thereto, followed by stirring for about 2 hours. Then, an amino triazine novolac curing agent 13.25 g and azobisisobutyronitrile (AIBN) 0.2 g were added thereto, followed by stirring for about 1 hour, thereby preparing a completely dissolved resin composition. Afterward, the same process as Example 1 was performed to prepare a measuring sample of Example 3.

### Comparative Example 1

A liquid crystal oligomer 31.92 g was mixed into an N,N′-dimethylacetamide (DMAc) solvent 43 g, followed by stirring for about 1 hour. N,N,N′,N′-tetraglycidyl-4,4′-methylenebisbenzenamine 21.28 g as an epoxy resin was added thereto, followed by stirring for about 2 hours. Then, dicyandiamide (DICY) 2.8 g and azobisisobutyronitrile (AIBN) 0.1 g were added thereto, followed by stirring for about 1 hour, thereby preparing a completely dissolved resin composition. The resin composition in an adequate amount was poured onto a shiny surface of a copper clad, and a film having a thickness of about 150 um was obtained by a film caster for a lab. The film was primarily dried in an oven at about 80° C. for 30 minutes to remove a volatile solvent. Then, the film was secondarily dried at about 120° C. for 60 minutes to obtain a film at a B-stage. The film was completely cured by maintaining a temperature of about 220° C., and pressure of 30 kgf/cm² for about 90 minutes. After the curing was completed, the film was cut into a size of 4.3 mm/30 mm to prepare a measuring sample.

### Comparative Example 2

A liquid crystal oligomer 16.24 g and an oligomer of phenyl methane maleimide 16.24 g were mixed into a N,N′-dimethylacetamide (DMAc) solvent 43 g, followed by stirring for about 1 hour. N,N,N′,N′-tetraglycidyl-4,4′-methylenebisbenzenamine 21.84 g as an epoxy resin was added thereto, followed by stirring for about 2 hours. Then, dicyandiamide (DICY) 1.68 g and azobisisobutyronitrile (AIBN) 0.1 g were added thereto, followed by stiffing for about 1 hour, thereby preparing a completely dissolved resin composition. Afterward, the same process as Comparative Example 1 was performed to prepare a measuring sample of Comparative Example 2.

### Comparative Example 3

A liquid crystal oligomer 16.24 g and an oligomer of phenyl methane maleimide 16.24 g were mixed into a N,N′-dimethylacetamide (DMAc) solvent 43 g, followed by stirring for about 1 hour. Bis(2,7-bis(2,3-epoxypropoxy))dinaphthalene methane 21.84 g which is a naphthalene-based epoxy resin was added thereto, followed by stirring for about 2 hours. Then, dicyandiamide (DICY) 1.68 g and azobisisobutyronitrile (AIBN) 0.1 g were added thereto, followed by stirring for about 1 hour, thereby preparing a completely dissolved resin composition. Afterward, the same process as Comparative Example 1 was performed to prepare a measuring sample of Comparative Example 3.

### Comparative Example 4

A liquid crystal oligomer 16.24 g and an oligomer of phenyl methane maleimide 16.24 g were mixed into a N,N′-dimethylacetamide (DMAc) solvent 43 g, followed by stirring for about 1 hour. N,N,N′,N′-tetraglycidyl-4,4′-methylenebisbenzenamine 21.84 g as an epoxy resin was added thereto, followed by stirring for about 2 hours. Then, an amino triazine novolac curing agent 1.68 g and azobisisobutyronitrile (AIBN) 0.1 g were added thereto, followed by stirring for about 1 hour, thereby preparing a completely dissolved resin composition. Afterward, the same process as Comparative Example 1 was performed to prepare a measuring sample of Comparative Example 4.

Evaluation on Thermal Property and Acid-Resistant Property of Insulating Film

Glass transition temperatures of Samples prepared by Examples and Comparative Examples were measured by using a differential scanning calorimeter (DSC, TA instruments), and coefficients of thermal expansion were measured by using a thermomechanical analyzer (TMA Q400, TA instruments) and increasing a temperature to 10° C./min under nitrogen atmosphere.

TABLE 1

| | Coefficient | Coefficient | | Acid |
|---|---|---|---|---|
| | of Thermal | of Thermal | Glass | Resistant |
| | Expansion | Expansion | Transition | Property |
| | (α₁) | (α₂) | Temperature | (Discolor- |
| Classification | (ppm/° C.) | (ppm/° C.) | (Tg) (° C.) | ation Y/N) |
| Example 1 | 45.6 | 119 | 223 | N |
| Example 2 | 46.6 | 125 | 210 | N |
| Comparative | 54.8 | 157 | 200 | Y |
| Example 1 | | | | |
| Comparative | 48.1 | 152 | 205 | Y |
| Example 2 | | | | |
| Comparative | 49.8 | 101 | 190 | N |
| Example 3 | | | | |
| Comparative | 46.8 | 115 | 200 | Y |
| Example 4 | | | | |

It may be appreciated from Table 1 above that the coefficients of thermal expansion in α₁ (50° C. to 100° C.) zone and α₂ (250° C. to 300° C.) zone of Examples 1 and 2 were relatively lower than those of Comparative Examples 1 to 4. Meanwhile, it may be appreciated that the coefficient of thermal expansion in α₂ zone of Comparative Example 3 was lower than those of Examples 1 and 2, but the glass transition temperature of Comparative Example 3 was remarkably deteriorated by using the dicyandiamide curing agent rather than the amino triazine novolac curing agent. In addition, it may be appreciated that in Examples 1 and 2, the glass transition temperatures of Examples 1 and 2 were excellent than those of Comparative Examples 1 to 4, and the discoloration due to the etching process using the acid solution was not generated by using the naphthalene-based epoxy resin. Therefore, it may be appreciated that the insulating resin composition including the liquid crystal oligomer, the naphthalene-based epoxy resin, the bismaleimide resin, and the amino triazine novolac curing agent according to the preferred embodiment of the present invention may be excellent as a resin composition for a printed circuit board.

The Sample prepared by Example 3 is a sample prepared according to another preferred embodiment of the present invention, wherein an inorganic filler is added to the composition to further emphasize the effect in view of the coefficient of thermal expansion.

### Preparation of Prepreg

### Example 4

An oligomer of phenyl methane maleimide 15.68 g and a liquid crystal oligomer 15.68 g were mixed into a N,N′-dimethylacetamide (DMAc) solvent 43 g, followed by stirring for about 1 hour. Bis(2,7-bis(2,3-epoxypropoxy))dinaphthalene methane 21.84 g which is a naphthalene-based epoxy resin was added thereto, followed by stirring for about 2 hours. Then, an amino triazine novolac curing agent 2.8 g and azobisisobutyronitrile (AIBN) 0.1 g were added thereto, followed by stirring for about 1 hour, thereby preparing a completely dissolved resin composition. When the stirring was completed, an E-glass glass fiber was impregnated into a varnish containing the resin composition and the reactant was put into the oven and dried at about 120° C. for 15 minutes. When the drying was completed, the temperature was increased up to 220° C., and the reactant was completely cured by maintaining a temperature of about 220° C., and pressure of 30 kgf/cm² for about 90 minutes to prepare a prepreg.

### Manufacture of Printed Circuit Board

### Example 5

Copper clad layers were laminated on both surfaces of the prepreg prepared by Example 4 above and a circuit pattern was formed thereon to manufacture a copper clad laminate. Then, after a drying process was performed under conditions of about 120° C. for 30 minutes, the insulating film prepared by Example 1 above was laminated on the copper clad laminate having the circuit pattern formed thereon, and was vacuum laminated by using a Morton CVA 725 vacuum laminator under conditions of about 90° C. and 2 MPa for about 20 seconds, thereby manufacturing a printed circuit board.

As set forth above, the insulating resin composition for the printed circuit board according to the preferred embodiment of the present invention, and the products manufactured by using the same may have the improved coefficient of thermal expansion and glass transition temperature properties, and the products manufactured by using the insulating resin composition may have the improved acid resistant property that the discoloration is not generated by the etching process using the acid solution.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An insulating resin composition for a printed circuit board, comprising:
a liquid crystal oligomer;
a naphthalene-based epoxy resin;
a bismaleimide resin; and
an amino triazine novolac curing agent.

2. The insulating resin composition as set forth in claim 1, wherein the insulating resin composition includes the liquid crystal oligomer in an amount of 10 to 30 wt %, the naphthalene-based epoxy resin in an amount of 20 to 40 wt %, the bismaleimide resin in an amount of 10 to 30 wt %, and the amino triazine novolac curing agent in an amount of 3 to 20 wt %.

3. The insulating resin composition as set forth in claim 1, wherein the liquid crystal oligomer is represented by the following Chemical Formula 1, Chemical Formula 2, Chemical Formula 3, or Chemical Formula 4: 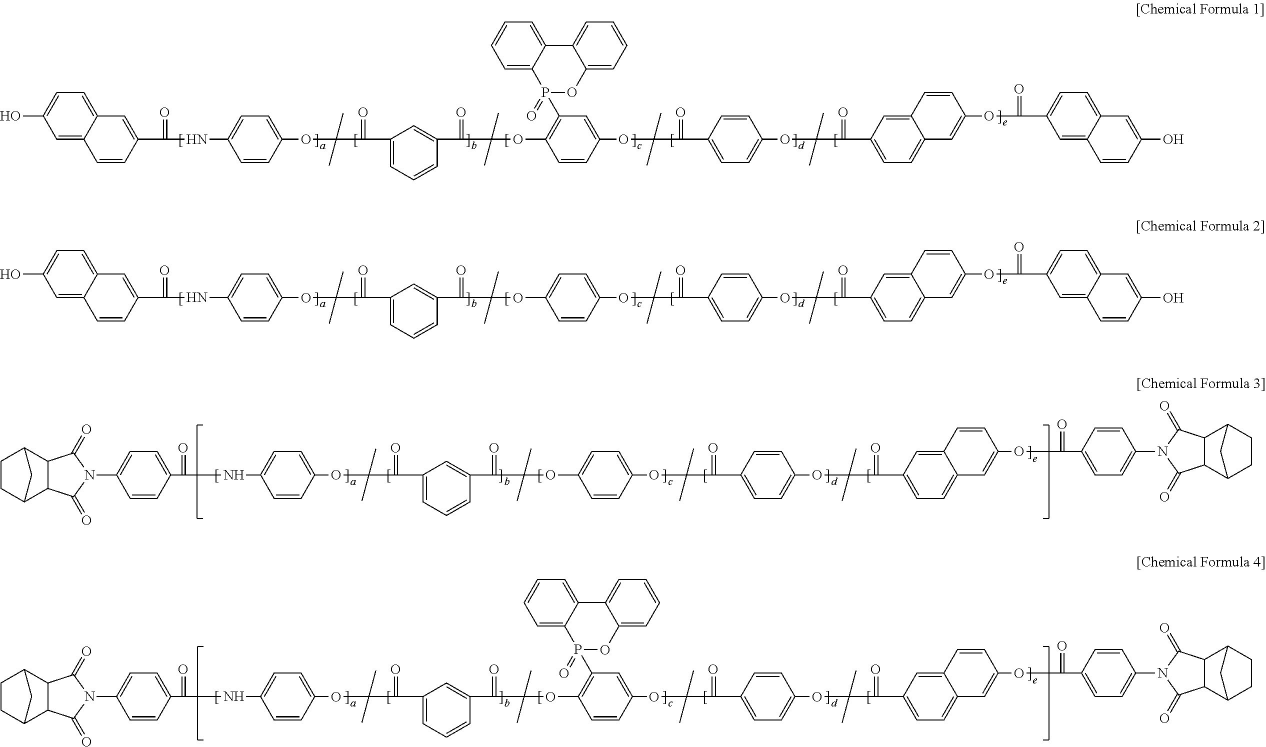
in Chemical Formulas 2 to 4, a is an integer of 13 to 26, b is an integer of 13 to 26, c is an integer of 9 to 21, d is an integer of 10 to 30, and e is an integer of 10 to 30.

4. The insulating resin composition as set forth in claim 1, wherein the naphthalene-based epoxy resin is represented by the following Chemical Formula 5, Chemical Formula 6, Chemical Formula 7, or Chemical Formula 8:

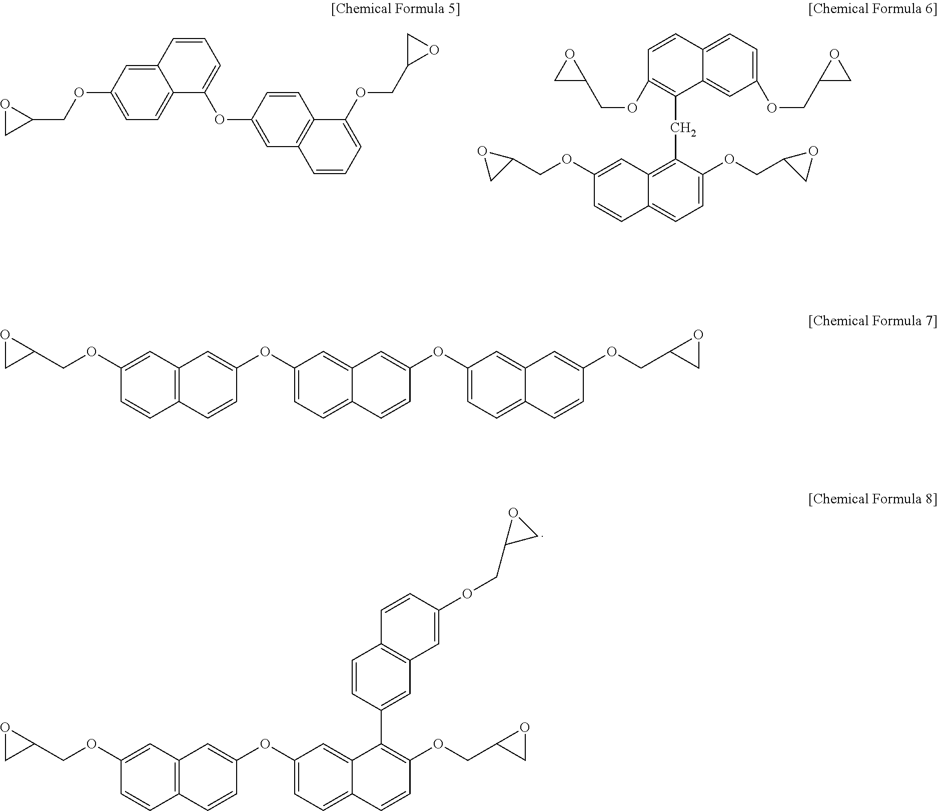 [SMILES: c1cc(OCC2CO2)c2ccc(Oc3cccc4cc(OCC5CO5)ccc34)cc2c1 ; c1cc2ccc(OCC3CO3)c(Cc3c(OCC4CO4)ccc4ccc(OCC5CO5)cc34)c2cc1OCC1CO1 ; c1cc2ccc(Oc3ccc4ccc(Oc5ccc6ccc(OCC7CO7)cc6c5)cc4c3)cc2cc1OCC1CO1 ; c1cc2ccc(Oc3ccc4ccc(OCC5CO5)c(-c5ccc6ccc(OCC7CO7)cc6c5)c4c3)cc2cc1OCC1CO1]

5. The insulating resin composition as set forth in claim 1, wherein the bismaleimide resin is represented by the following Chemical Formula 9 or Chemical Formula 10:

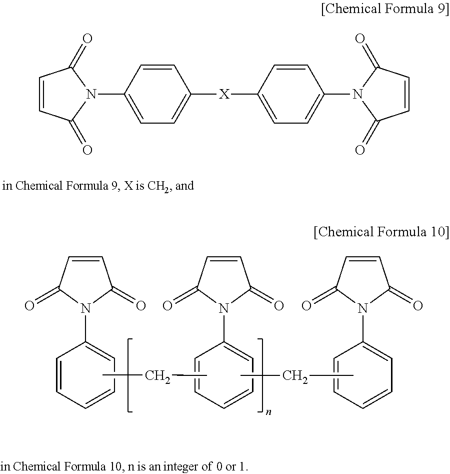

6. The insulating resin composition as set forth in claim 1, wherein the amino triazine novolac curing agent includes an amino group and a hydroxyl group, and is represented by the following Chemical Formula 11, Chemical Formula 12, or Chemical Formula 13:

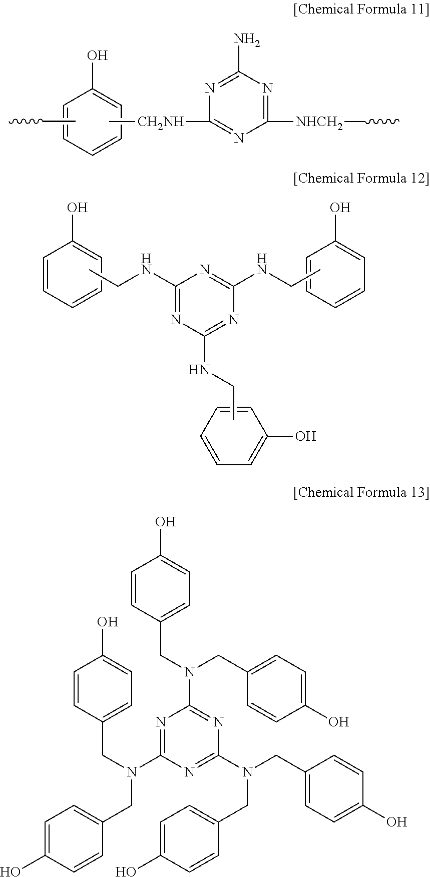

7. The insulating resin composition as set forth in claim 1, further comprising an inorganic filler, a coupling agent, a dispersant, an initiator, a surface treating agent, a defoaming agent, and a curing accelerator.

8. The insulating resin composition as set forth in claim 7, wherein the inorganic filler is included in an amount of 100 to 400 parts by weight based on 100 parts by weight of the insulating resin composition, and is at least one selected from silica (SiO₂), alumina (Al₂O₃), barium sulfate (BaSO₄), talc, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃).

9. The insulating resin composition as set forth in claim 7, wherein the initiator is at least one selected from azobisisobutyronitrile (AIBN), dicumyl peroxide (DCP) and di-tertiarybutyl peroxide (DTBP).

10. The insulating resin composition as set forth in claim 7, wherein the curing accelerator is at least one selected from a metal-based curing accelerator, an imidazole-based curing accelerator, and an amine-based curing accelerator.

11. An insulating film prepared by applying and curing a varnish containing the insulating resin composition as set forth in claim 1 on a substrate.

12. A prepreg prepared by impregnating an inorganic fiber or an organic fiber into a varnish containing the insulating resin composition as set forth in claim 1.

13. The prepreg as set forth in claim 12, wherein the inorganic fiber or the organic fiber is at least one selected from a glass fiber, a carbon fiber, a polyparaphenylenebenzobisoxazol fiber, a thermotropic liquid crystal polymer fiber, a lithotropic liquid crystal polymer fiber, an aramid fiber, a polypyridobisimidazole fiber, a polybenzothiazole fiber, and a polyarylate fiber.
